(19) United States
(12) Patent Application Publication
(10) Pub. No.: US 2008/0108176 A1
(43) Pub. Date: May 8, 2008

(54) Phase change memory and fabricating method thereof

(75) Inventor: Jiuh-Ming Liang, Chu-Tung (TW)

Correspondence Address: RABIN & Berdo, PC, 1101 14TH STREET, NW, SUITE 500, WASHINGTON, DC, 20005, US

(73) Assignee: INDUSTRIAL TECHNOLOGY RESEARCH INSTITUTE, Hsinchu (TW)

(21) Appl. No.: 12/003,298

(22) Filed: Dec. 21, 2007

Related U.S. Application Data
(62) Division of application No. 11/131,242, filed on May 18, 2005.

(30) Foreign Application Priority Data
Jan. 7, 2005 (CN) 094100497

(51) Int. Cl. H01L 21/06

(52) U.S. Cl. 438/102; 257/E21.068

(57) ABSTRACT

A phase change memory including a phase change layer, a first electrode, and a porous dielectric layer formed with a plurality of pores. The porous dielectric layer is formed between the phase change layer and the first electrode. Therefore, the phase change layer may make contact with the first electrode thorough the pores thereby decreasing the contact areas of the phase change layer and the first electrode.

This application claims the benefit of Taiwan Patent Application No. 94100497, filed on Jan. 7, 2005, which is hereby incorporated by reference for all purposes as if fully set forth herein.

### BACKGROUND

1. Field of Invention

The invention relates to an electrode structure, and in particular to an electrode structure that is applicable for phase change memory to reduce the contact area between the electrode and the phase change layer for lowering the operation power and operation current.

2. Related Art

Most electronic equipment uses different types of memories, such as DRAM, SRAM and Flash memory or a combination of these memories based on the requirements of the application, the operating speed, the memory size and the cost considerations of the equipment. The current developments in the memory technology field include FeRAM, MRAM and phase-change memory. Among the memories, phase-change memory will be mass manufactured in the future.

The phase change semiconductor memory, which is a kind of non-volatile memory, records data by way of the resistance variation cased by the material's phase change. The phase change semiconductor memory may still stores data when power is off. The crystallization of the phase change material (e.g. Ge2Sb2Te5) is changed by way of electrical heating. The different crystallization phases of the material have different resistances indicating different digital values, ex. 0 and 1.

Current is to supplied to the selected memory cell when the phase change memory writes data. The phase change layer is heated by the heating electrodes such that phase transition is formed in the phase change layer. However, the heating electrodes connect with the transistor, which provides limit currents; thus, reducing the write-in current for the phase change layer for phase transition has become the main development.

The general approach to reduce the write-in current is by reducing the contact areas between the phase change layer and the electrodes. In the prior art, tapered points, spacers, trenches/sidewalls, or edge contacts are adopted to reduce the contact areas.

U.S. Pat. Nos. 6,746,892 and RE37259 disclose tapered points to reduce the contact areas. The bottom electrodes with tapered points are formed by etching many times. U.S. Pat. Nos. 6,545,287, 6,744,088 and 6,635,951 employ spacers to reduce the contact areas. The spacers are formed by etching and CMP processes additionally included in the original process.

U.S. Pat. No. 6,646,297 and U.S. Pat. No. 6,437,383 employ trenches/sidewalls to reduce the contact areas. The electrodes in the form of trenches/sidewalls are formed by way of trenches, etching, and sidewall height adjustment process additionally included in the original process. The approaches of the prior art face the problems of large changes in the manufacturing process or increasing difficulty in controlling the whole process.

Further, Ha; Y. H. (Samsung, Symposium on VLSI Technology 2003) reduces the contact areas by way of edge contact. However, difficulty is increased in the consequent process due to reducing of the thin film thickness by way of edge contact. Besides, mask alignment greatly affects the contact areas of the edges. Because it is difficult to reduce the width and the length of the electrodes simultaneously, the area of the memory cell may be reduced such that memory density is affected.

The technology trend is towards reducing the contact areas, thereby reducing the current and power necessary for the operation of the phase change memory. However, the technology disclosed in the prior art may not be easily integrated with the current process, which increases the difficulty in manufacturing. Therefore, there is a need to provide another electrode structure to reduce the contact area between the electrode and the phase change layer.

### SUMMARY

Accordingly, the invention relates to a phase change memory that substantially obviates one or more of the problems of the related art. The contact area between the electrode and the phase change layer is reduced and the operation power and operation current is lowered.

In accordance with the embodiment, a phase change memory includes a phase change layer; a first electrode formed on one surface of the phase change layer; and a porous dielectric layer formed therebetween and having a plurality of pores formed thereon such that the phase change layer and the first electrode make contact with each other through the pores.

In accordance with another embodiment, a phase change memory includes a phase change layer; a first electrode and a second electrode formed on the two surfaces of the phase change layer respectively; a first porous dielectric layer formed between the phase change layer and the first electrode, and having a plurality of pores formed thereon such that the phase change layer and the first electrode make contact with each other through the pores; and a second porous dielectric layer formed between the phase change layer and the second electrode, and having a plurality of pores formed thereon such that the phase change layer and the second electrode make contact with each other through the pores.

According to the embodiment, a porous dielectric layer is formed between the phase change layer and the electrode to reduce the contact area of the phase change layer and the electrode by way of the thin film forming condition, self alignment of nano material, or nano grains/lines that are used as a mask for coating.

According to the embodiment, the contact area between the electrode and the phase change layer is reduced and the operation power and current is lowered through the disclosed phase change memory.

According to the embodiment, the contact area between the electrode and the phase change layer is controllable.

According to the embodiment, the manufacturing process does not need modification for the disclosed phase change memory, thus the difficulty of the manufacturing process is not increased.

In the following description, for purposes of explanation, numerous specific details are set forth in order to provide a thorough understanding of the invention. It will be apparent, however, to one skilled in the art that the invention can be practiced without these specific details. In other instances, structures and devices are shown in block diagram form in order to avoid obscuring the invention.

### BRIEF DESCRIPTION OF THE DRAWINGS

The above and other objects, features and other advantages of the invention will be more clearly understood from the following detailed description when taken in conjunction with the accompanying drawings, in which:

FIG. 1 illustrates one embodiment of the electrode structure of the phase change memory of the invention;

FIGS. 2A˜2B illustrate another embodiment of the electrode structure of the phase change memory of the invention;

FIG. 3 illustrates another embodiment of the electrode structure of the phase change memory of the invention;

FIGS. 4A˜4F illustrate the manufacturing process of the phase change memory of the invention;

FIG. 5 illustrates another manufacturing process of the phase change memory of the invention; and

FIG. 6 illustrates another manufacturing process of the phase change memory of the invention.

### DETAILED DESCRIPTION

Reference will now be made in greater detail to a preferred embodiment of the invention, an example of which is illustrated in the accompanying drawings. Wherever possible, the same reference numerals are used throughout the drawings and the description to refer to the same or like parts. Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

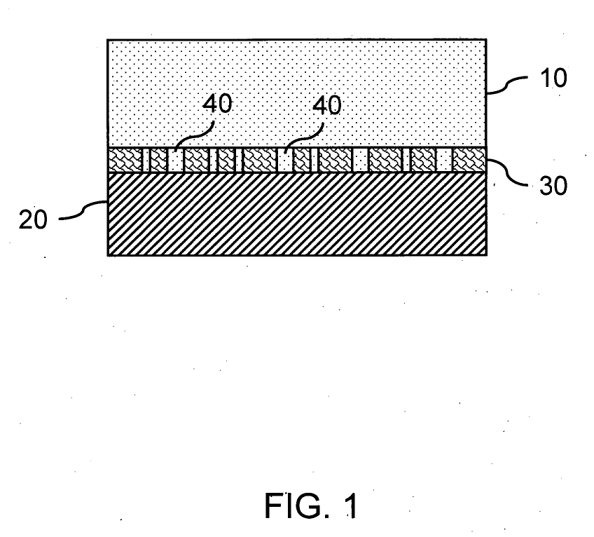

FIG. 1 illustrates one embodiment of the electrode structure of the phase change memory of the invention. FIG. 1 only shows a single memory (or memory cell). The actual MRAM array can be composed of several memories as shown in FIG. 1.

One surface of the phase change layer 10 is provided with an electrode 20 for supplying electrical signals, thereby heating the phase change layer 10 to change state, e.g., crystallization state or amorphous state.

A porous dielectric layer 30 having a plurality of pores 40 is formed between the phase change layer 10 and the electrode 20. The porous dielectric layer 30 is made from porous dielectric material, e.g., Silicon Oxide (SiOx), Silicon Nitride (SiNx), Aluminum Nitride (AlNx), or Silicon Carbonate (SiC). The pores 40 of the porous dielectric layer 30 are filled with the phase change layer 10 such that contact between the phase change layer 10 and the electrode 20 is formed though the pores 40. Therefore, the contact area between the electrode and the phase change layer is reduced.

The phase change layer 10 may use doped eutectic SbTe, e.x. AgInSbTe, GeInSbTe, or GeSbTe compound, e.g. Ge2Sb2Te5.

The electrode 20 not only makes contact with the phase change layer 10 for conductivity but also uses it as a heat sink. Material with stable chemical characteristics and high heat conductivity may be adopted for the electrode 20, e.g., TiN, TaN, TiW, TiAlN, Mo, W, or C.

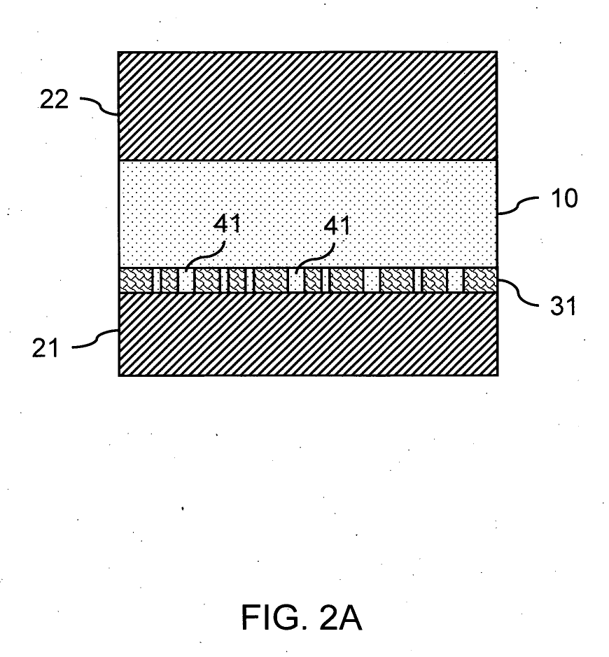

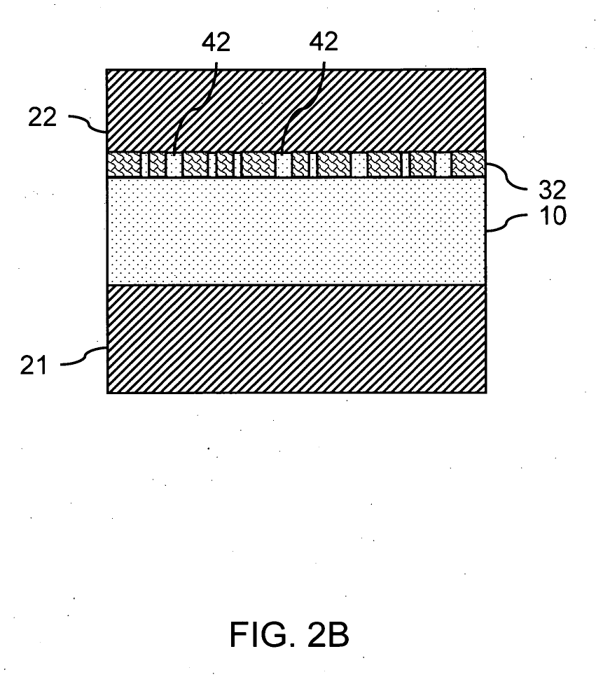

FIG. 2 illustrates another embodiment of the electrode structure of the phase change memory of the invention. FIG. 2 only shows a single memory (or memory cell). The actual MRAM array can be composed of several memories as shown in FIG. 2A.

The two surfaces of the phase change layer 10 are formed with a first electrode 21 and a second electrode 22 for supplying electrical signals, thereby heating the phase change layer 10 to change state, e.g., crystallization state or amorphous state.

A porous dielectric layer 31 having a plurality of pores 41 is formed between the phase change layer 10 and the first electrode 21. The porous dielectric layer 31 is made from porous dielectric material, e.g., Silicon Oxide (SiOx), Silicon Nitride (SiNx), Aluminum Nitride (AlNx), or Silicon Carbonate (SiC). The pores 41 of the porous dielectric layer 31 are filled with the phase change layer 10 such that contact between the phase change layer 10 and the first electrode 21 is formed though the pores 41. Therefore, the contact area between the first electrode 21 and the phase change layer 10 is reduced.

In another embodiment, a porous dielectric layer 32 having a plurality of pores 42 is formed between the phase change layer 10 and the second electrode 22, as illustrated in FIG. 2B.

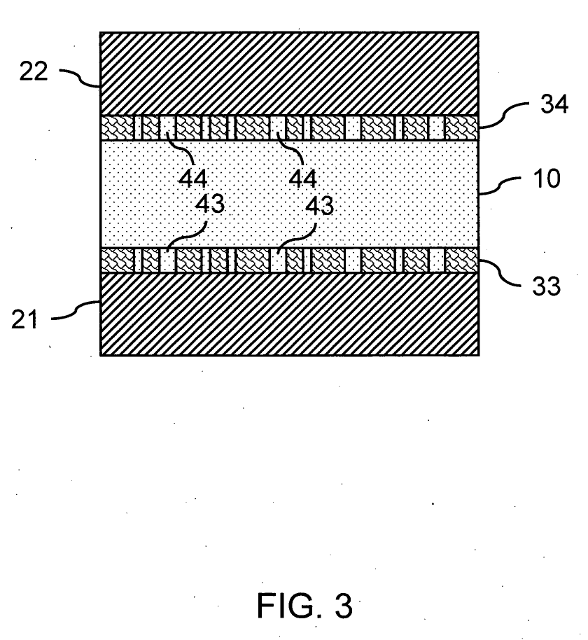

FIG. 3 illustrates another embodiment of the electrode structure of the phase change memory of the invention. FIG. 3 only shows a single memory (or memory cell). The actual MRAM array can be composed of several memories as shown in FIG. 3.

The two surfaces of the phase change layer 10 are formed with a first electrode 21 and a second electrode 22 for supplying electrical signals, thereby heating the phase change layer 10 to change state, e.g., crystallization state or amorphous state.

A first porous dielectric layer 33 having a plurality of pores 43 is formed between the phase change layer 10 and the first electrode 21, while a second porous dielectric layer 34 having a plurality of pores 44 is formed between the phase change layer 10 and the second electrode 22. The first porous dielectric layer 33 and the second porous dielectric layer 34 are made from porous dielectric material, e.g., Silicon Oxide (SiOx), Silicon Nitride (SiNx), Aluminum Nitride (AlNx), or Silicon Carbonate (SiC). The pores 43 of the first porous dielectric layer 33 and the pores 44 of the second porous dielectric layer 34 are filled with the phase change layer 10 such that contact between the phase change layer 10 and the first electrode 21, and contact between the phase change layer 10 and the second electrode 22, are formed though the pores 43 and the pores 44. Therefore, the contact area between the first electrode 21 and the phase change layer 10, and the contact area between the second electrode 22 and the phase change layer 10 are reduced.

The phase change layer 10 may use doped eutectic SbTe, e.g. AgInSbTe, GeInSbTe, or GeSbTe compound, e.g. Ge2Sb2Te5.

The first electrode 21 and the second electrode 22 not only make contact with the phase change layer 10 for conductivity but also are used as a heat sink. The material with stable chemical characteristic and high heat conductivity may be adopted for the first electrode 21 and the second electrode 22, e.g., TiN, TaN, TiW, TiAlN, Mo, W, or C.

Formation of the porous dielectric layers in the aforementioned embodiments is given in detail as follows.

In one embodiment, the block co-polymer material is coated on the electrodes. Thus, the pores are formed by self arrangement. Then the dielectric layer is deposited in the pores and the block co-polymer material is removed such that the pores are leaved. Then the phase change material is coated on the layer such that the phase change layer and the electrodes make contact with each other through the pores.

In one embodiment, a Latex material is coated on the electrodes. Thus, the pores between particles are formed by self arrangement. Then the dielectric layer is deposited in the pores and the Latex material is removed such that the pores are leaved. Then the phase change material is coated on the layer such that the phase change layer and the electrodes make contact with each other through the pores.

In one embodiment, the pores are formed by way of uncontinuous films or an island structure caused by surface tension of the dielectric material in the thin film process.

In one embodiment, the pores are formed by way of removing the nano grains/lines that are used as a mask for coating.

The principle of the reduced contact areas in the embodiments of FIGS. 1˜3 is given as follows.

The surface coverage of the porous dielectric layer is F. The contact area of the electrode is A, while the contact area is reduced by f×A, i.e. the contact area is (1−f)×A. If the Joule heat power (energy density) necessary for phase change of each contact region is the same, the original contact area is A, the current for phase change is I, and the resistance is R, then the energy density for phase change is I²R/A. Suppose the contact areas of n numbers are reduced from A to a surface coverage f, then na=A×(1−f).

The resistance of the contact pores is increased due to the reduced contact area. The resistance is inversely proportional to the contact area, thus ra=RA, wherein r is the resistance of the small pores.

The current of each small pore is i. Because the energy density for phase change is fixed, i²r/a=I²R/A, and i=I×(a/A).

The total current of all the small pores is ni, ni=nI×(a/A)=I×(1−f). Because f<1, the total current of the electrodes through the small pores is lower than that of a single electrode without pores, and the total resistance is r/n=RA/na=R/(1−f), which is higher than that of a single electrode without pores, wherein n resisters each with r ohms are connected in parallel. Thus, the complex electrodes formed by the porous dielectric layer and the electrode may reduce the contact area and the write current.

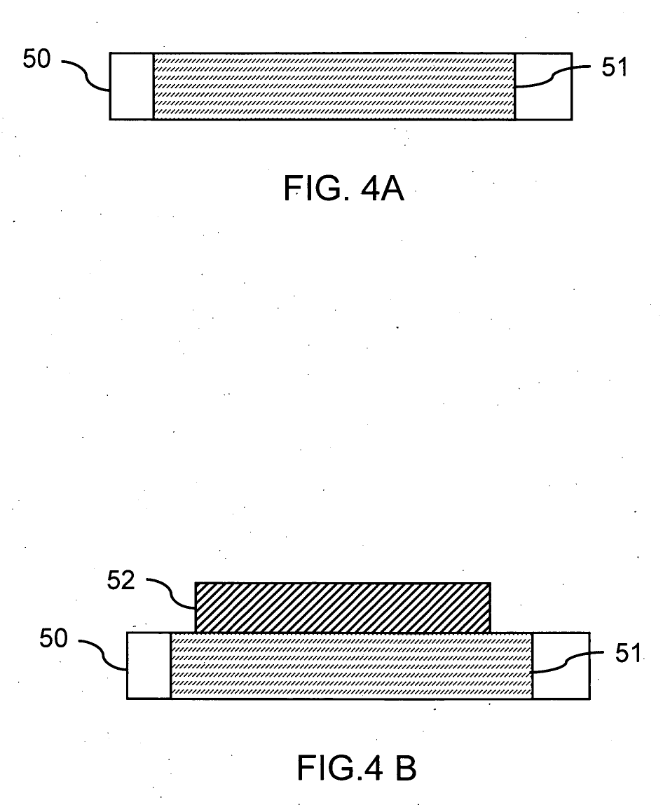

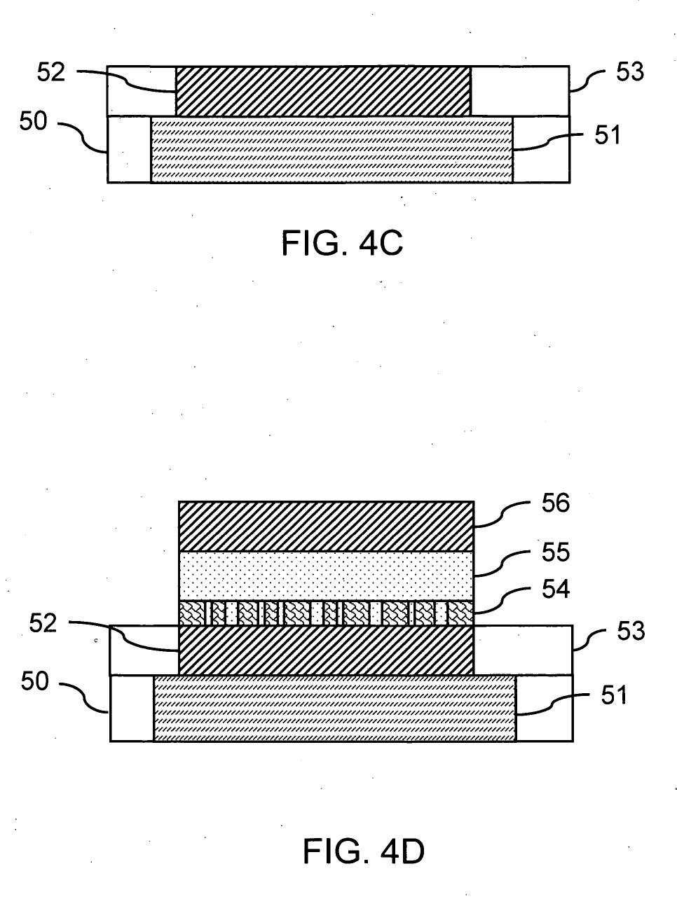

FIGS. 4A˜4F illustrate the manufacturing process of the phase change memory in FIG. 2A. The order of the steps is not completely unchangeable or indispensable. Some steps can be performed simultaneously, omitted, or added. The steps outlined herein describe the characteristics of the invention broadly and simply and are not intended to restrict the order and the number of times a particular step should be performed.

A metal layer 51 is formed in a dielectric layer 50 as a conductive line for the electrode to make contact with the external components. A first electrode 52 is deposited, which is then etched to a predetermined size according to the manufacturing process design rule and element size. A first dielectric layer 53 is formed surrounding the first electrode 52 as an insulated layer, as illustrated in FIG. 4C. In one embodiment, the first dielectric layer 53 may be processed with a Chemical Mechanical Polishing process.

Then, the porous dielectric layer 54, the phase change layer 55, and the second electrode 56 are formed in sequence. The phase change layer 55 makes contact with the first electrode 53 through the pores of the porous dielectric layer 54, as illustrated in FIG. 4D. In one embodiment, the porous dielectric layer 54, the phase change layer 55, and the second electrode 56 are etched for adjusting the predetermined size. The second dielectric layer 57 is deposited as an insulated layer for the porous dielectric layer 54, the phase change layer 55, and the second electrode 56. In one embodiment, the second dielectric layer 57 may be processed with a Chemical Mechanical Polishing process. Then, a metal layer 58 is formed, as illustrated in FIGS. 4E˜4F.

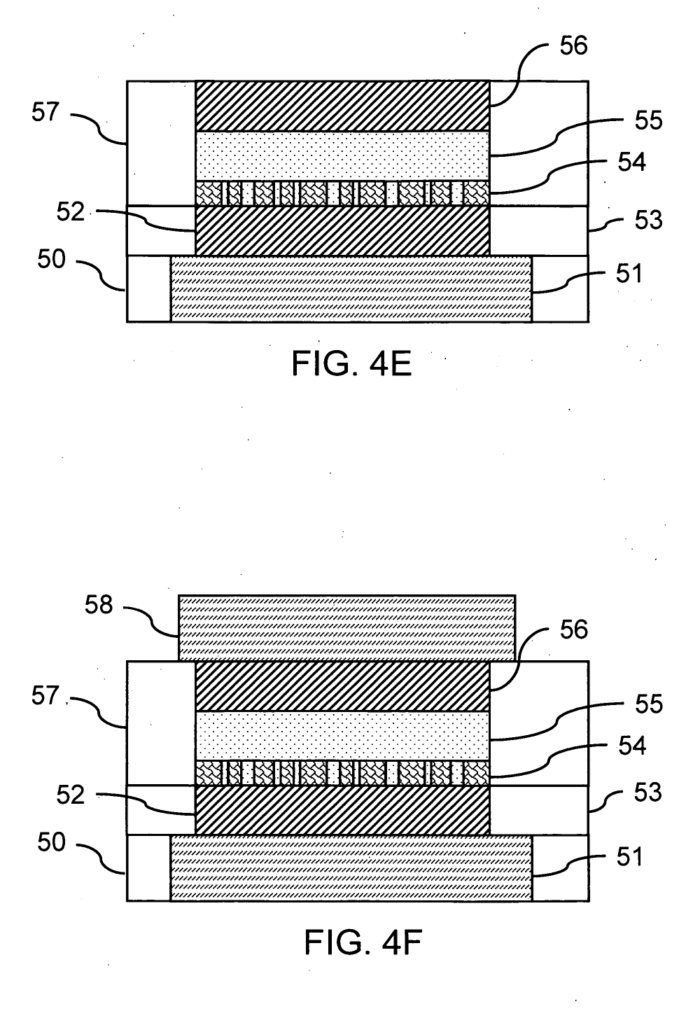

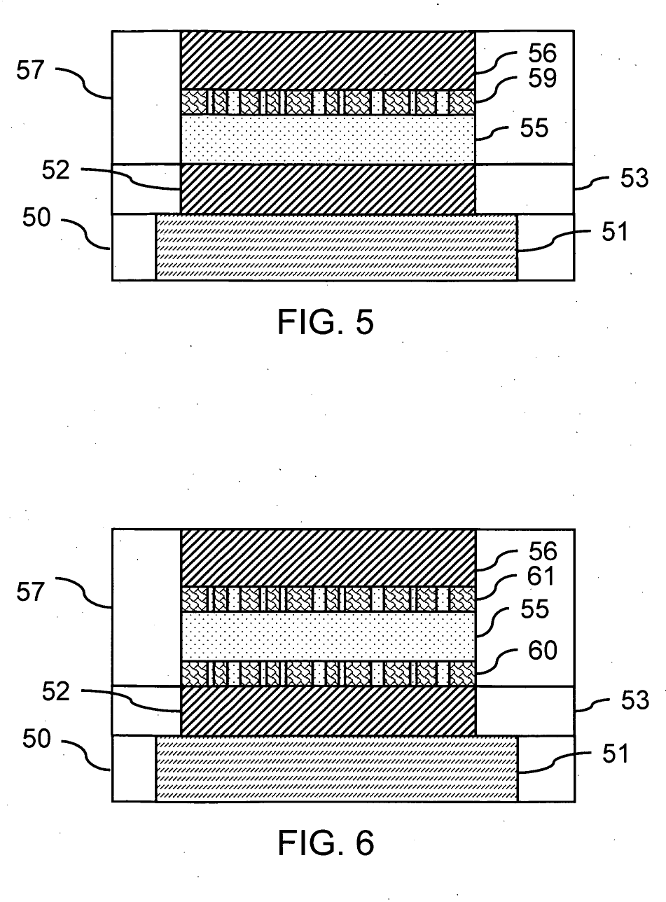

In another embodiment, after forming the first electrode 52, a phase change layer 55, a porous dielectric layer 59 and a second electrode 56 are then formed, as illustrated in FIG. 5.

In another embodiment, after forming the first electrode 52, a first porous dielectric layer 60, a phase change layer 55, a second porous dielectric layer 61 and the second electrode 56 are then formed, as illustrated in FIG. 6.

In the embodiments of FIG. 5 and FIG. 6, the manufacturing of the porous dielectric layer is the same or similar to that of the embodiments in FIGS. 1˜3.

A porous dielectric layer is formed between the electrodes and the phase change layer by way of thin film forming or nano technology in accordance with the phase change memory of the invention. The contact area is thus reduced and the operation power and current is lowered. The manufacturing process does not need modification for the disclosed phase change memory of the invention, thus the difficulty of the manufacturing process is not increased.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1-12. (canceled)

13. A manufacture method of a phase change memory comprising steps of:
forming a first electrode;
forming a first dielectric layer surrounding the first electrode;
forming a first porous dielectric layer having a plurality of pores formed thereon on the first electrode; and
forming a phase change layer on the first porous dielectric layer.

14. The manufacture method of claim 13 further comprises a step of forming a second electrode on the phase change layer.

15. The manufacture method of claim 14 further comprises a step of forming a second dielectric layer on the second electrode.

16. The manufacture method of claim 13 further comprises steps of:
forming a second porous dielectric layer having a plurality of pores formed thereon on the phase change layer; and
forming a second electrode on the second porous dielectric layer.

17. The manufacture method of claim 13, wherein the pores are made from block co-polymer material.

18. The manufacture method of claim 13, wherein the pores are made from Latex material.

19. The manufacture method of claim 13, wherein the pores are formed by way of the uncontinuous film or the island structure formed in the thin film process.

20. The manufacture method of claim 13, wherein the pores are formed by way of removing the nano grains/lines which are used as mask for coating.
